(19) United States
(12) Patent Application Publication
(10) Pub. No.: US 2025/0231500 A1
(43) Pub. Date: Jul. 17, 2025

(54) SMART EQUIPMENT FRONT END MODULE METROLOGY

(71) Applicant: Nanoverse Technologies Ltd, Beaverton, OR (US)

(72) Inventors: Jeff Albelo, Beaverton, OR (US); William Robertson, Beaverton, OR (US)

(73) Assignee: Nanoverse Technologies Ltd, Beaverton, OR (US)

(21) Appl. No.: 19/090,358

(22) Filed: Mar. 25, 2025

Related U.S. Application Data
(63) Continuation-in-part of application No. 18/404,765, filed on Jan. 4, 2024.
(63) Continuation-in-part of application No. 18/391,516, filed on Dec. 20, 2023.

(51) Int. Cl. G03F 7/00

(52) U.S. Cl. CPC G03F 7/706851; G03F 7/706845; G03F 7/707; G03F 7/70733

(57) ABSTRACT

A method for using a smart EFEM in a semiconductor wafer process facility that incorporates at least one metrology testing device in a metrology unit positioned in operational proximity to the pre-alignment unit. The pre-alignment unit has a chuck that is used for both pre-alignment and for metrology, that two robotic arms shuttle the Si wafers onto while they are laying idle awaiting to be selected for processing. The metrology unit uses a bright elliptical scan light with light rays that are aligned in one axis and angled in another. The metrology scanning in the preferred embodiment is Bright Field-Dark Field metrology with coordinated motion between the metrology stage's movement, the rotation of the modulator wheel, the shuttering of the line scan cameras and if rotational scanning is performed, the rotation of the chuck. This provides a frame of reference for each scan image that eliminates or minimizes the need for image stitching.

### PRIORITY CLAIM TO A NONPROVISIONAL APPLICATION

THIS APPLICATION IS A CONTINUATION IN PART OF U.S. patent application Ser. No. 18/404,765, FILED Jan. 4, 2024, WHICH IS INCORPORATED BY REFERENCE HEREIN IN ITS ENTIRETY.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to increasing the efficiency of semiconductor wafer processing and microchip fabrication systems, and more particularly to introducing equipment and methods into the fabrication modules that allows enhanced metrology to be performed on the Si wafers during idle time. This addresses a solution to the technical problem of lengthy microchip production times by improving an existing technological process.

### BACKGROUND

The process of fabricating microchips from an array of electrical circuits placed on top of a semiconductor wafer, is a complex technical operation that involves extensive handling of the wafer as it moves sequentially through a host of different fabrication stations. On average, a wafer is processed by 65 different machines as the microscopic circuit patterns are built on multiple layers of various materials, and only after these steps have been repeated hundreds of times, is the microchip finally completed.

To make microchips, semiconductor wafers have successive layers of different electrical circuits affixed to their planar faces. This is done through a plethora of cycles including all or some of these steps: polishing, edge zone marking, oxidation, photolithography, etching, deposition and ion implanting, contact hole formation, metal interconnect, dicing and electrical die sorting and testing. Interspersed among these steps is the metrology analysis and tracking.

The semiconductor fabrication process is slow as the wafers must be handled through numerous Equipment Front End Modules (EFEM) which pass the wafers through to the various other processing modules. An EFEM is the mainstay of semiconductor automation, shuffling silicon wafers between ultra-clean storage carriers and a variety of processing, measurement and testing modules. EFEM's access the wafers via a stacked cassette style wafer carrier, that manually is entered into a rack in a front opening universal port (FROUP). Each EFEM generally handles one or two wafers at a time which are robotically and precisely moved in and out of these wafer carriers. After the EFEM robotic wafer handler transfers these wafers to a process module, the remainder of the wafers sit idle in the wafer carrier in the FROUP. Between the processings coordinated from the various EFEM units, the wafer carriers with their multiple wafers, are transported to different metrology test units to map and test the wafers at their various stages of processing before moving on to another EFEM. The metrology steps are time consuming but necessary.

Altering the location of the metrology, as well as enhancing the scanning speed, accuracy and precision of the metrology with physical and methodological improvements would speed up production and provide more data and better tracking of the Si wafers during processing. This would cut wafer processing time and increase quality control, thus fulfilling two long felt needs in the microchip fabrication industry. This invention utilizes and combines known and new technologies in a unique and novel configuration to overcome the aforementioned problems and accomplish this.

### SUMMARY

In accordance with various embodiments, a Smart EFEM, integrating different metrology modules, equipment improvements and BF-DF metrology examination techniques within the EFEM, and interspersed between the wafer's process flow to obtain data about the wafer such as flatness, surface defects, film thickness, uniformity and edge/bevel/front/back inspection is provided. By doing this, metrology need not occur after the wafers have gone through a processing module. It is done simultaneously along with throughput semiconductor wafer fabrication. This is a step forward in yield enhancement for Si wafers in production, as it utilizes the previous down time of wafers in the wafer carriers (but not yet into the process flow), to perform metrology data collection and tracking.

In one aspect, a metrology module and analysis module added into the EFEM, along with a larger, dual purpose pre-alignment and metrology chuck and a robotic wafer handler (preferably with dual robotic arms) for the movement of wafers (waiting to be injected into the process flow) on and off the chuck for pre-alignment and wafer scanning with measurement data, tracking data and wafer scan positional coordinates, can occur.

In another aspect, a semiconductor equipment processing front end module (EFEM) equipped with a novel metrology technique that alternates wafer processing with wafer metrology, to allow inspection of the wafer's surface contamination, flatness uniformity, film thickness, tow-dimensional and three-dimensional topography of idle wafers.

In another aspect, an EFEM metrology unit designed for spatial efficiency by performing full Si wafer metrology scans in one half the space of conventional metrology units, and with a greater photon density light that is better structured for surface flaw examination, and with a coordinated motion scanning device that eliminates or minimizes image stitching by providing a coordinate point from a common frame of reference for each data image or data point that the line scan cameras acquire.

Various modifications and additions can be made to the embodiments discussed without departing from the scope of the invention. For example, while the embodiments described above refer to particular features, the scope of this invention also includes embodiments having different combination of features and embodiments that do not include all the above-described features.

### BRIEF DESCRIPTION OF THE DRAWINGS

A further understanding of the nature and advantages of particular embodiments may be realized by reference to the remaining portions of the specification and the drawings, in which like reference numerals are used to refer to similar components.

FIG. 1 is a diagrammatic top view of a prior art generic semiconductor processing facility;

FIG. 2 is a diagrammatic side view of a prior art generic EFEM integrated with a generic single semiconductor processing module;

FIG. 3 is a diagrammatic top view of the smart EFEM integrated into a generic semiconductor processing facility;

FIG. 4 is a diagrammatic side view of the preferred embodiment Smart EFEM integrated with a generic single semiconductor processing module;

FIG. 5 is a representative drawing of the prior art metrology scan light beam;

FIG. 6 is a representative drawing of the improved metrology elliptical scan light beam imposed over the outline of a pixel array from a line scan camera and a conventional metrological scan light beam;

FIG. 7 is a representative drawing of the path of the collimated light component of the scan light beam exiting the cylindrical lens as seen in the first axis;

FIG. 8 is a representative perspective view of the light beam shape provided to the modulator as seen in perspective in the first axis;

FIG. 9 is a representative drawing of the path of the converging light component of the scan light beam exiting the cylindrical lens as seen in the second axis;

FIG. 10 is a representative drawing of the light beam shape provided to the modulator as seen in perspective in the second axis.

FIG. 11 is a representative drawing of the elliptical light source beam provided to the modulator and through to the metrology chuck;

FIG. 12 is a representative drawing of a coordinated motion BF-DF metrology module as utilized in a smart EFEM;

FIG. 13 is drawing of a partial scan pass of the coordinated motion BF-DF metrology module; and

FIG. 14 is an enlarged view of a coordinated motion metrology scan path showing the pre scan runup locations.

### DETAILED DESCRIPTION

Reference will now be made in detail to embodiments of the inventive concept, examples of which are illustrated in the accompanying drawings. The accompanying drawings are not necessarily drawn to scale. In the following detailed description, numerous specific details are set forth to enable a thorough understanding of the inventive concept. It should be understood, however, that the embodiments described are provided for illustrative purposes and are not intended to limit the scope of the invention.

It will be understood that, although the terms first, second, etc. may be used herein to describe various elements, these elements should not be limited by these terms. These terms are only used to distinguish one element from another. For example, a first attachment could be termed a second attachment, and, similarly, a second attachment could be termed a first attachment, without departing from the scope of the inventive concept.

It will be understood that when an element or layer is referred to as being “on,” “coupled to,” or “connected to” another element or layer, it can be directly on, directly coupled to or directly connected to the other element or layer, or intervening elements or layers may be present. In contrast, when an element is referred to as being “directly on,” “directly coupled to,” or “directly connected to” another element or layer, there are no intervening elements or layers present.

Like numbers refer to like elements throughout. As used herein, the term “and/or” includes all combinations of one or more of the associated listed items.

As used in the description of the inventive concept and the appended claims, the singular forms “a,” “an,” and “the” are intended to include the plural forms as well, unless the context clearly indicates otherwise. It will also be understood that the term “and/or” as used herein refers to and encompasses all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise indicated, all numbers herein used to express quantities, dimensions, and so forth, should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically

The terms “semiconductor and microchip, semiconductor chip, chip and integrated circuit (IC)” are used interchangeably herein. Integrated circuits are built out of an array of circuits (including but not limited to transistors, diodes, resistors, and capacitors) fabricated on top of a semiconductor, generally on a 150, 200 or 300 mm Si wafer that is diced to yield the individual microchips. These microchips perform logic operations and store data-generally handling all the processing tasks of most consumer computers. There are numerous integrated circuits put on a semiconductor wafer which is diced into numerous smaller components. These smaller diced sections of the semiconductor wafer are commonly called semiconductors, microchips, chips or integrated circuits.

As used herein, the term “EFEM” refers to an Equipment Front End Module which is the mainstay of semiconductor automation, shuffling silicon wafers between ultra-clean wafer carriers and a variety of processing, measurement and testing modules. The EFEM has one or more load ports, pre-aligners, buffer modules, robotic wafer handlers, and computers for analysis, data storage and data transfer.

As used herein, the term “wafer carrier” refers to any device that stores multiple wafers and can be inserted into a loading port of an EFEM for eventual distribution of the individual wafers, via the robotic wafer handler, into the semiconductor fabrication stream via the pre-alignment module.

As used herein the term “interferometer metrology” is a method of metrology that superimposes two or more sources of light to create an interference pattern, which can be measured and analyzed to detect thickness variances or minute imperfections in the topography of the spectral surface of the semiconductor wafer extremely small measurements made Interferometry can quickly discern parallelism and unintended thickness pattern changes in wafers or layers added to wafers. These patterns can then be measured and analyzed to ensure they are within the specifications of the manufacturing process.

As used herein, the term “ellipsometer metrology” refers analysis of the wafers using a device that measures a change in polarization, represented as an amplitude ratio and the phase difference, as light reflects or transmits from a test sample. This is compared to a model. The measured response depends on optical properties and thickness of the test sample. Ellipsometry is primarily used to determine film thickness and optical constants, however, it is also applied to characterize composition, crystallinity, roughness, doping concentration, and other material properties associated with a change in optical response.

As used herein, the term “metrology” means the science of measurement. In the context of semiconductor manufacturing, metrology refers to various quality assurance scientific devices and methods used to measure the tolerances, structural deviations and dimensions of the SI wafer as it is built into a microchip.

As used herein, the term “specular surface” means a type of surface with a reflectance often described as a mirror-like reflection of light from the surface. In specular reflection, the incident light is reflected into a single outgoing direction as the angle of incidence equals the angle of reflection. Semiconductor flatness and surface roughness measurements may be determined by the reflection (concentrated or diffuse) of an incident light beam.

As used herein, the term “wafer” refers to a thin slice of a semiconductor material such as pure Silicon (generally from a cylinder configured with a diameter of 150, 200 or 300 mm). They are also known as a CPU wafers, or silicon wafers, and are used as the starting point for the production of central processing units (CPUs) and other microchip integrated circuits. These wafers are highly polished to have a specular surface.

As used herein, the term “structured light” refers to one or more lines of variable (i.e. controlled) width, pitch, and wavelength which will cover a predefined area. A source light is passed through an optical modulator or other optical device to add structure to the light. It will be referred to as the Light Frame of Reference (LFOR. The light is selected from a group of light emitting devices consisting of the following: a light emitting diode (LED), a laser and a filament source.

As used herein, the term “image capture data array (ICDA)” refers to the image capture point data measured by a sensor from the reflection of structured light that was projected onto a test sample at one or more locations. Computer algorithmic analysis of this point cloud ICDA will reveal the geometric distortions of the test sample.

As used herein, the term ICDA optical sensor refers to an array of more than one optical sensor selected from the group consisting of a CMOS sensor, a photodetector, a photomultiplier tube (PMT) and a charged coupled device (CCD). Generally, these are arranged as a line sensor that is 1 pixel high and thousands of pixels long.

As used herein, the term “wafer pre-aligner” (pre-aligner) means a mechanical device that accurately positions and aligns semiconductor wafers between their transfer from the wafer carrier to the semiconductor fabrication process equipment or metrology module. Generally, thus is done referencing an edge zone flat spot put on the edge of the wafer, edge notches of fiducial marks. This ensures that the wafer, is properly oriented and positioned precisely on the piece of semiconductor fabrication equipment in the semiconductor production modules, so that the integrated circuits are built up correctly and with minimal defects. Metrology testing in the Smart EFEM occurs on the platter of the pre-aligner.

As used herein, the term “robotic wafer handler” is a computerized robotic device designed to automate and facilitate the handling of silicon wafers during the semiconductor manufacturing process. Wafer handlers shuttle semiconductor wafers between wafer carriers in the loading ports of the EFEMs, pre-aligners, and the semiconductor processing tools in the production modules, where various manufacturing tasks throughout the semiconductor production lifecycle are completed. Automated wafer handling systems can be found throughout various Back End of Line (BEOL) or Front End of Line (FEOL) manufacturing processes as the robotic wafer handler facilitates the transfer of wafers between process tools.

As used herein, the term “metrology module” refers to an assembly of metrology components used to examine and analyze a wafer for identification (tagging) as well as film thickness, surface topography, defects, dimensions and tolerances and other critical parameters that affect the operation of a semiconductor. It is generally positioned above the metrology chuck of the pre-alignment module. Herein, it is a BF-DF metrology device using coordinated motion in conjunction with the elliptical scan light. It shares its line scan data (which may be images or just raw metrology data) with a localized main computer which communicates this data to the semiconductor processing system's operational mainframe computer.

As used herein “sequencing unit” refers to an electronic device that coordinates the transfer of wafers via the robotic arm, about the EFEM and the semiconductor processing module and metrology module.

As used herein the term “position sensor” refers to any of a plethora of devices that generate and relay data/electrical pulses that allow for the determination of the position (two- or three-dimensional location), and/or velocity (linear or rotational) of the device they are associated with. Commonly, they are connected to the drive motor or motor shaft of the device's prime mover. Devices herein that utilize these position/speed sensors are the A axis drive of the modulator wheel, the X, Y and Z axis drives of the metrology stage, and the C axis drive of the chuck. In the preferred embodiment this sensor may be an encoded motor shaft, a Hall effect sensor, a stroboscopic tachometer, or the equivalent, placed on the device or any part thereof its motor assembly.

As used herein, the term “wafer map” refers to a set of instructions showing the location of everything the customer has or is building on a Si wafer. It lays out the grid pattern of the semiconductors or transistors and their parts on the wafer as well as the wafer's edge notches and fiducial markings.

As used herein, the term “BF-DF” refers to bright field-dark field metrology where a structured light beam is presented at an angle to the target Si wafer's surface, and the resultant spectral and refracted light is acquired by scan cameras and analyzed to determine the topography of the wafer's surface.

As used herein, the term “C axis” refers to the rotational axis (theta) of the pre-alignment/metrology chuck that the Si platter resides on for either alignment or scanning.

As used herein, the term “A axis” refers to the rotational axis (theta) of the modulator wheel.

As used herein, the term “coordinate system” refers to an X Y C coordinate where the X and Y are left-handed Cartesian coordinates of the X axis and Y axis of the Si wafer, and the C is the theta rotation of the Si wafer about the Z axis (which is referred to herein as the C axis). It is to be noted the Z axis motor assembly raises or lowers the metrology chuck (or in some designs, the metrology stage) along the Z axis while the C axis motor assembly rotates the metrology chuck in theta about/around the Z axis.

As used herein, the term “camera shuttering” refers to the operation of the shutter of the line sensor cameras to capture of a set of sequential pixelated photos of the area being scanned by the metrology device. A common speed for BF-DF camera shuttering is 300 kHz.

As used herein, the term “approximately” when referring to the pixel array size means the stated size number of pixels plus or minus 30% in length and 300% in height. A standard pixel array of a line scan camera is 16,000 pixel long and 1 pixel high.

As used herein, the term “structured light” refers to a beam of light that has been passed through an optical modulator's grids or slits to project a known pattern of grids or bars onto the Si wafer surface to be examined. These bars deform when striking surfaces on the wafer. Cameras capture reflected or refracted pixelated images of these and a connected computer can algorithmically process these images to produce a three-dimensional picture showing the depth, height and surface information of the surfaces in the scene.

As used herein, the term “collimated” refers to a light that is collimated (made up of parallel rays) in one or both axes.

As used herein, the term “blue light laser” refers to any laser light between the wavelengths of 400 and 500 nm although the preferred specific blue light describe herein is around the 445 nm+/−20 nm wavelength.

It takes over 65 pieces of specialized equipment to make a microchip from a SI wafer. The non-contact measurement of silicon wafers is critical for ensuring accurate thickness, topography, of these components. Defining and obtaining accurate thickness measurements are essential for reducing anomalies in patterning and packaging problems during semiconductor fabrication. Similarly, detecting anomalies in the spectral surface and built-up integrated circuits is critical for quality control and correction of processing operations.

Herein is disclosed a device and method to increase the overall output of semiconductor production facility as well as enhance the physical data and mapping of the semiconductor wafers fabricated therein. It accomplishes this by integrating novel high-speed BF-DF metrology equipment and methods, into the production process stream at the entry EFEM, to test and map the wafers 2 while they are sitting idle in the wafer carrier 4. It uses a novel, modified Smart EFEM technology with a wafer loading port, an integrated metrology module containing, at least one BF-DF metrology device, a pre-alignment module, a robotic wafer handler, at least one localized main computer, a rotational motor assembly coupled to the pre-alignment chuck, and a sequencing module. The Smart EFEM has its own pre-aligner with a large diameter metrology platter replacing the standard positioning platter (AKA chuck). It is used in wafer alignment and metrology. This Smart EFEM can conservatively cut the processing time of a semiconductor chip by 20%.

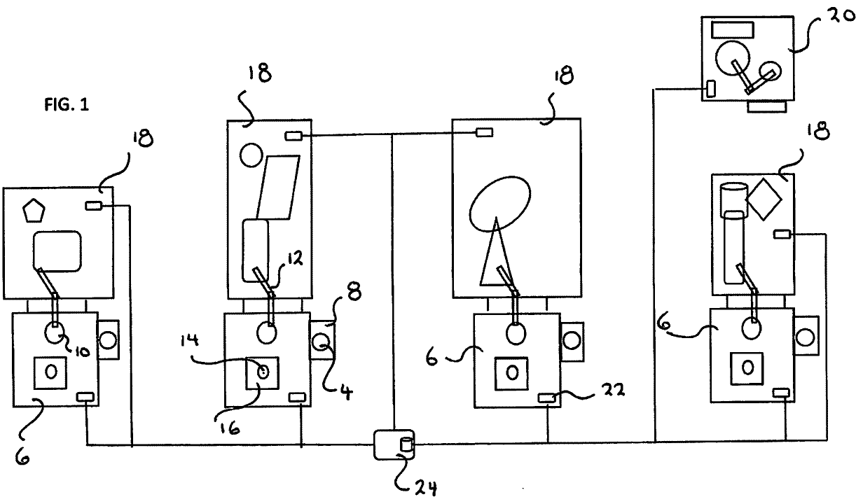

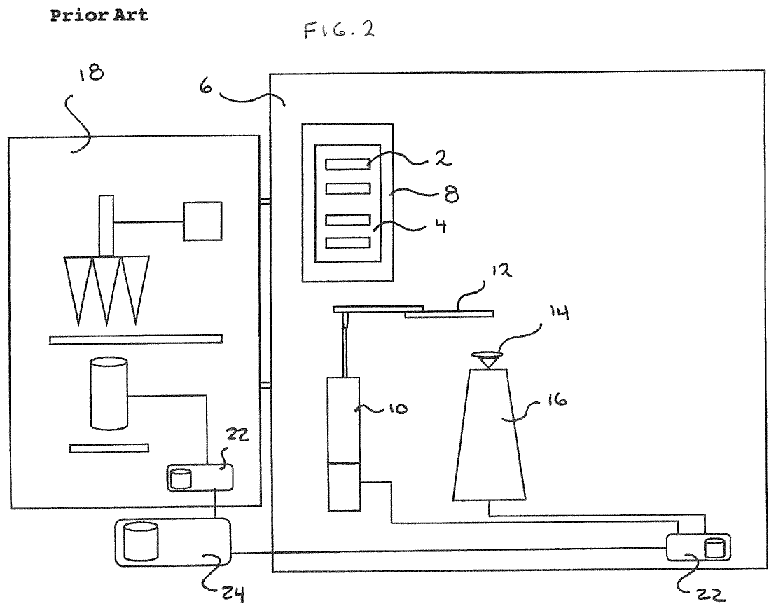

Looking at FIGS. 1 and 2, (which represent pre-existing art) it can be seen that in the conventional processing of Si wafers, a series of coded semiconductor wafers 2 are loaded into a wafer carrier 4 known as a FOUP (Front Opening Universal Port); FOSB Box (Front Opening Shipping Box); SMIF Pod (Standard Mechanical Interface Pod); Open Cassette; or Coinstack Horizontal Wafer Stacker. These wafer carriers 4 are loaded into an EFEM 6 which is a standardized interface via its loading port 8. A robotic wafer handler 10 with at least one moveable arm 12 with end effectors, extracts the wafers 2 from the wafer carrier 4 and manually places them onto a chuck 14 of a pre-aligner 16 where they are accurately indexed to the proper orientation and location to enter that specific semiconductor processing module 18 to build that portion of the integrated circuits on the wafer 2.

During the time these wafers 2 are having their integrated circuits built on them, the remainder of the wafers 2 in the wafer carrier 4 remain idle. Once all the wafers 2 have been processed and are back in the wafer carrier 4, the wafer carrier 4 is manually removed from the loading port 8 of the EFEM 6 and put into a metrology module 20 for wafer testing/analyzing and tracking. After this is completed, the wafer carrier 4 of tested/analyzed and tracked wafers 2 are removed from the metrology module 20 and loaded into the next EFEM 6 coupled to the next sequential semiconductor processing module. Throughout this production, localized main computers 22 track the wafer's ID and the metrology data of each wafer 2 and communicate this to the system's operational mainframe computer 24.

The time that it takes to complete this semiconductor processing flow and fully dice the wafers 2 into microchips is lengthy. Since only one or a few of the wafers 2 are processed at a time, the bulk of the wafers 2 remain idle in the wafer carrier 4 in the loading port 8 of the EFEM 6. This is wasted time in an already lengthy process. There is too much idle time for the wafers when being processing via a conventional EFEM 6. This time could be used to gather metrology and tracking data about individual wafers 2 so they could proceed directly between semiconductor processing modules 18, bypassing any intermediary metrology module 20.

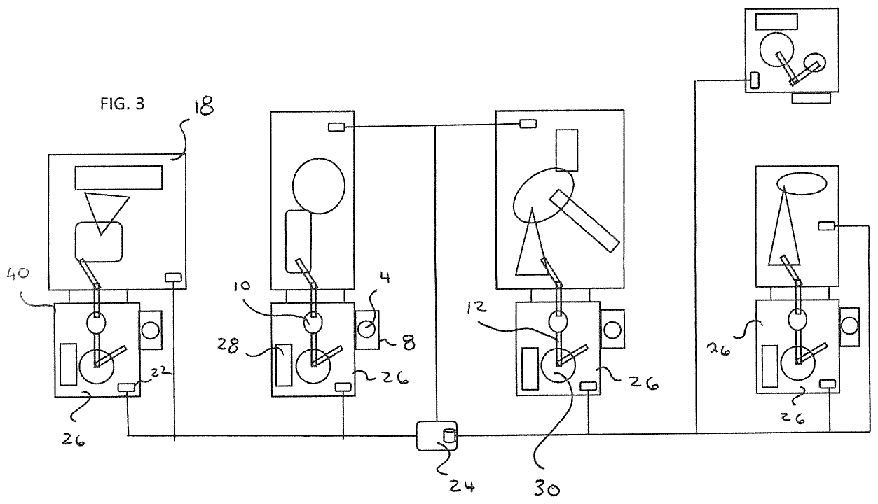

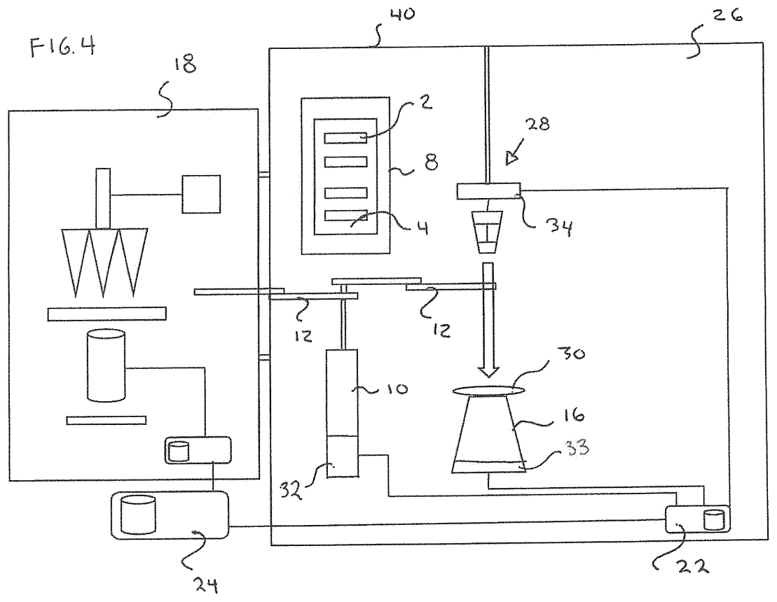

Looking at FIGS. 3 and 4, the Smart EFEM can best be explained. Here a Smart EFEM 26 is a dust-proof walled enclosure 40 that can be seen integrated with a semiconductor processing module 18, wherein a metrology module 28 is located above a pre-alignment module 16 that has been coupled to a large diameter pre-alignment/metrology chuck 30. (Here, large indicates it is larger in diameter, or at least the equivalent in diameter, as that of the Si wafer 2 the robotic arm 12 places on the metrology chuck 30, to support the wafer 2 in its entirety and eliminate metrology errors in the wafer's flatness and other measurements.)

Preferably, there is also a second robotic arm 12 on the robotic wafer handler 10 so that wafers 2 can be simultaneously shuttled between the wafer carrier 4 and the pre-alignment module 16; the pre-alignment module 16 and the semiconductor processing module 18; the semiconductor processing module 18 and the wafer carrier 4; and the pre-alignment module 16 and the wafer carrier 4.

There is a sequencing unit 32 in communication with the main computer 22 that via a sequencing signal from the main computer 22 to the robotic wafer handler 10, coordinates the shuffling of the unprocessed wafers 2 between the wafer carrier 4 and the per-alignment module 16 for metrology testing while the processed (or to be processed) wafers 2, are shuttled between the wafer carrier 4 and the pre-alignment module 16; the pre-alignment module 16 and the semiconductor processing module 18; and the semiconductor processing module 18 and the wafer carrier 4. The sequencing unit 32 is responsible for affecting the robotic arm's movement of the wafers from the wafer carrier 4 going to be processing and the wafers 2 from the wafer carrier 4, going for metrology testing.

There is a localized main computer 22 in the EFEM that is in data communication with the semiconductor facility's system's operational mainframe computer 24. The EFEM main computer also controls the operations of all the electromechanical equipment in the EFEM (motors, pneumatics, etc.) through various controllers. The controllers are interfaces between the computer's instructions and the actual motors that carry out the movements.

The metrology module 28, the robotic wafer handler 10 and the pre-alignment module 16 each use operational controllers (be it a microprocessor, microcontroller or computer) that control the motions of their electro-mechanical devices. The robotic wafer handler 10 has a sequencing controller 32 that directs the movement of its arms and how the wafers are shuttled about; the metrology module uses a motion controller 34 to direct the coordinated actions of the motor assemblies (including the rotational C axis motor of pre-alignment chuck 30), the light source and the BF-DF camera shuttering of the metrology module 28, and the pre-alignment module 16 has an alignment controller 33 that coordinates the motions of the chuck to pre-align wafers for processing. This amalgamation of the operational controllers 32, 33 and 34, the localized main computer 22 and the operational mainframe computer 24 may be configured in a plethora of different ways.

The operational mainframe computer 24 houses all the history of each SI wafer including its wafer map, fabrication data, its testing data, and its location data. It is to be noted that the pre-alignment of the Si wafer for processing occurs on the pre-alignment chuck 30 with the wafer's location and orientation performed by the metrology module 28, and the BF-DF scan of the Si wafer is also done on the same chuck 30 (now a metrology chuck) by the metrology module 28.

If the metrology of the idle wafers 2 is performed in each EFEM while semiconductor fabrication is occurring on one or a few of the remaining wafers 2, there is no need to send the wafer carrier 4 to a metrology module 20 between the successive semiconductor processing modules 18. This is a huge savings of time.

In operation, the Smart EFEM 26 accepts the manual insertion of a set of wafers 2 arranged in a wafer carrier 4, into its loading port 8, located on the outside of one of the walls of the EFEM enclosure 40. The sequencing controller 32 signals the robotic wafer handler 10 to manipulate one of its robotic arms 12 to withdraw the first wafer 2 from the wafer carrier 4 and place it on the metrology chuck (also the pre-alignment chuck) 30 of the pre-alignment module 16. The metrology module 28 identifies the wafer and correctly orientates it for insertion into a semiconductor wafer processing module 18. This data is provided to the main computer 22. Its location and identification data are sent to the semiconductor processing system's operational mainframe computer 24 (directly or via the localized main computer 22) where it is stored. It may also optionally be examined by the metrology module 28 if it is the first wafer out of the wafer carrier.

The main computer 22 based on the sequencing of the wafers, initiates the metrology examination. Note that subsequent wafers 2 from the wafer carrier 4, will not have their processing immediately after their metrology examination. Any metrology data (analyzed or in raw data form) from the metrology module is sent to the localized main computer 22 for storage, analysis and or transfer. This analyzed metrology data is transmitted to the semiconductor processing system's operational mainframe computer 24.

Upon completion of the metrology examination (which is not optional, just optional currently for the first wafer), the sequencing unit 32 signals the robotic wafer handler 10 to manipulate one of its two robotic arms 12 to remove the first wafer 2 in its correct physical orientation and transfer it to a semiconductor wafer processing module 18. The main computer 22 signals the semiconductor processing module to begin its processing.

While the processing of the first wafer is underway, the sequencing controller 32 signals the robotic wafer handler 10 to use one of its two robotic arms 12 to shuttle the other idle wafers 2 (one at a time) between the wafer carrier 4 and the chuck 30 on the pre-alignment module 16. When these idle wafers 2 (not yet into the semiconductor process flow) are individually placed on the metrology chuck 30, the main computer 22 signals the motion controller 34 to run the metrology unit 28 to identify and examine the wafer 2, sending its metrology data to the semiconductor processing system's operational mainframe computer 24 via localized computing devices 22 connected to the metrology module 28. The main computer 22 signals the sequencing controller 32 to move the robotic wafer handler's robotic arms 12 to return the now metrologically examined wafer back to the wafer carrier 4. The time to process a wafer exceeds the time to metrologically examine a wafer 2, so the wafers lying idle in the wafer carrier 4 will continue to be examined one by one between processing of the wafers in the semiconductor processing module 18 until a wafer is finished processing.

The examination of the idle wafers 2 will continue sequentially through the wafers loaded in the wafer carrier 10, however the main computer sets an operational priority wherein wafer processing takes priority to metrology examination. After processing of this first wafer 2 has been completed, the main computer 22, via the sequencing controller 32, signals the robotic wafer handler 10 to manipulate one of its two robotic arms 12 to transfer the processed first wafer from the semiconductor processing module 18 back to the wafer carrier 4. (Each wafer, examined or not, will be placed onto the pre-alignment module 16 prior to entering a semiconductor wafer processing module 18.) The main computer 22 now selects the next sequential unprocessed wafer as per its priority, and as soon as the idle wafer currently on the pre-alignment chuck 30 is finished with its metrology examination, the sequencing repeats the steps of shuttling the wafers between the wafer carrier 10 and the pre-alignment module 16, following the priority rules, until all the wafers 2 in the wafer carrier 4 have been identified and analyzed for structural anomalies. After all the wafers have been examined, only the production sequencing will remain.

It is to be noted that in the sequencing, the wafer's processing takes priority over the wafer's examination because processing is a much lengthier process. In this manner the time the wafers spend in a Smart EFEM is identical to the time the wafers spend in a conventional EFEM except the metrology of all the wafers in that wafer carrier is completed and there need not be a separate step where the wafer carrier is sent to a metrology module. Rather, the wafer carrier may be transferred to the next Smart EFEM and semiconductor processing module.

It is also to be noted, that the sequencing may occur in the reverse order, where the metrology examination may be performed on the wafers that have been returned to the wafer carrier after they have been processed.

It is to be noted, that there may be more than one set of logic instructions for the sequencing of wafer processing and inspection. In the way of a first example, the first wafer may have a full metrology examination when placed on the chuck 30 before being shuttled to the semiconductor processing module. The sequencing module then sequentially sends wafers 2 to the pre-alignment/metrology chuck 30 based on the following priority: wafers to undergo processing with an open availability in the semiconductor processing module first, wafers just undergoing metrology examination second. FIG. 8 shows the priority rules of the sequencing module of the Smart EFEM.

The actual set of logic instructions will be time optimized and vary based on the length of the time the metrology examination/s take, and the length of time the wafer processing takes. Either way, since there are generally only one or two wafers able to be processed at any time and the time to metrologically examine a wafer is much shorter. There will be numerous idle wafers that are metrologically examined between wafer processing.

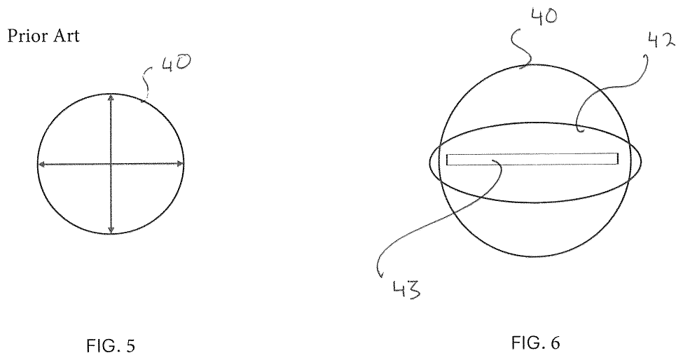

The speed of the metrology examination is limited by many elements, however the precision and accuracy of the data and images acquired is dictated in large part by the photon density of the light that strikes the scan area of the Si wafer. Looking at FIG. 5 it can be seen that a conventional source light beam 40 used for BGF-DF metrology, has a round configuration. The shape the source light beam 42 of the coordinated motion metrology module 28 uses to conducts its examination scans in the EFEM is elliptical. This mimics the shape of line scan camera's pixel array 43. It has a higher photon density that that of the conventional source light beam 40 as is evidenced by its smaller area for the same given number of photons. (See FIG. 6)

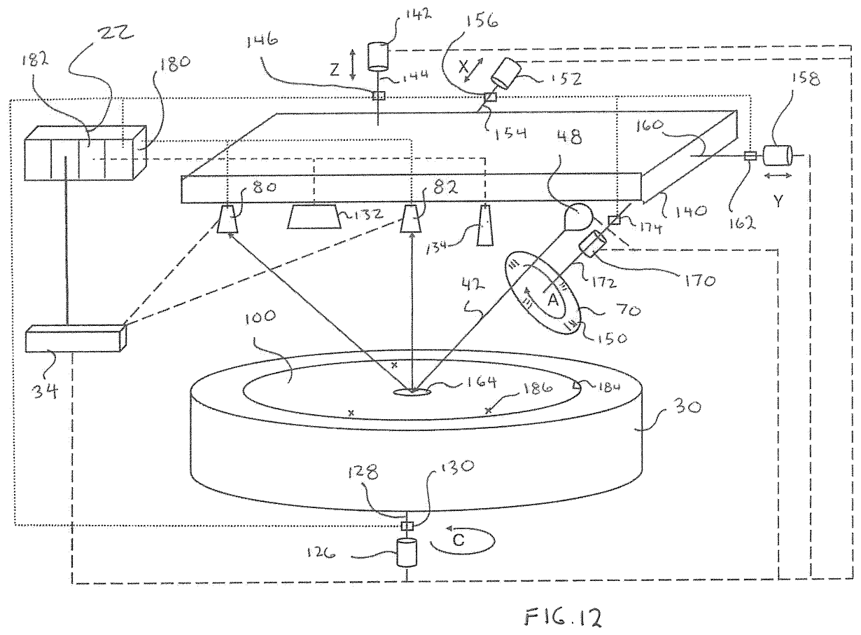

The light source 48 that the metrology unit 28 uses produce this brighter, elliptical light beam 42 is described with reference to FIG. 11. The laser 50, in the preferred embodiment, a 445 nm (blue light) diode laser, produces a laser light that is transmitted through a fiber optic cable 52 to provide a point source 54 of divergent light. The light from the point source 54 passes through a high NA (low f number) aspherical achromatic convex laser collimating lens 56 (placed at least one focal length away from the point source 54) and emerges as a collimated beam of blue light 58 that is directed to a dichroic mirror 60. In the preferred embodiment, this dichronic mirror 60 is customized with thin film coatings on its surface to reflect light in the 490 nm and lower range and transmit the remainder of the light (white light). This reflects the collimated beam 58 toward the aspheric converging lens 62 which converges the light into a circular spot pattern on the laser Phosphor 64.

When this light hits the laser Phosphor 64, since the laser Phosphor is a Lambertian material, emits divergent white light uniformly in 180 degrees. It is to be noted that the laser Phosphor is sensitive to the amount of energy that is put into it and can burn up if too much power is provided. For this reason, the aspheric converging lens 62/laser Phosphor 64 assembly is tunable. Although optimally to be placed at one focal length from the laser Phosphor 64, the converging lens 62 can be moved closer to, or further from the laser Phosphor 64 adjusting the size and photon density of the spot of light on the laser Phosphor. (Alternatively, the laser Phosphor may be moved with respect to the converging lens.) This is done to maximize the amount of white light generated without damaging the laser Phosphor 64, and while still retaining as much of the light collimation and uniformity as possible.

The aspheric converging lens 62 is selected as it has a high numerical aperture which provides high angle of acceptance of the white light which is sent back through the aspheric lens 62 by the phosphor 64, while maintaining an acceptable level of uniformity in the photon density. This lens 62 collimates the white light 66 which passes through the dichroic mirror 60 and through a cylindrical lens 68. This cylindrical lens 68 only has curvature in one axis and thus focuses light only in one axis. From this lens 68 exits a different shaped light beam, that of a focused line of light rather than a circle. Thus, an elliptical light beam 42 is provided to the modulator wheel 70. This light beam 42 is now smaller and brighter that the original circle since the same number of photons now occupy a smaller area, and the uniformity of photon density has increased slightly. The actual length of the elliptical light beam 42 is sized to coincide approximately with the length of the line sensors 43. (Since the height of a single pixel is in the order of 0.5 microns, this elliptical light beam, although a line light source, will not approximate the aspect ratio of the line sensor, just the length. See FIG. 6.)

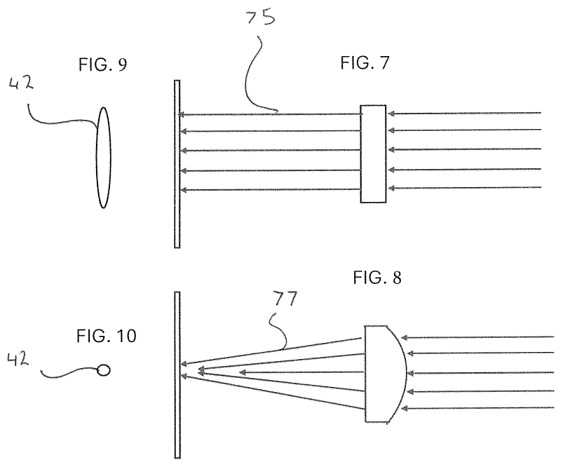

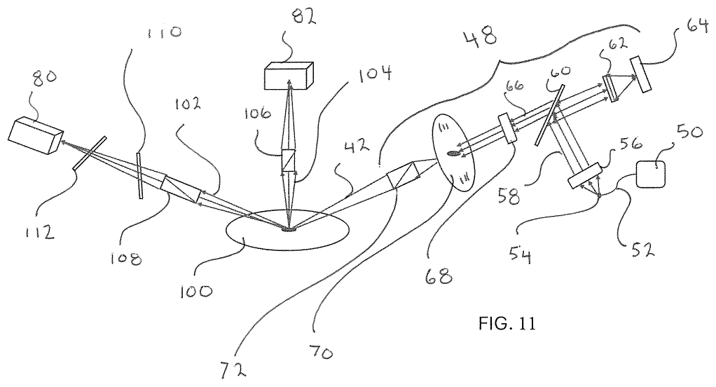

The elliptical light beam that leaves the cylindrical lens 68 is collimated and focused in the one axis 75 as seen from a first axis view (top view in FIG. 7), and convergent 77 in the second axis view (side view in FIG. 9). This results in an elliptical shaped light as seen in perspective in FIGS. 8 and 10 from the top and side views respectively. The cylindrical lens 68 shaped the light beam to an elliptical light source to more closely coincide with the linear shape of the line sensors 43. Clearly, the aspect ratio of the line sensors 43 cannot be maintained because of the diminutive size of a single pixel, so the ellipse much closer approximates the line sensor's length not its height. (See FIG. 6)

The use of this cylindrical lens 68 before the modulator 70 has an unexpected result, as the intent of this lens was just to focus, size and shape the light beam close to that of the line sensors in the BF and DF cameras 80 and 82, to increase the photon density (brightness), and to slightly increase the photon uniformity and eliminate wasted light. By using this cylindrical lens 68, the sampling light beam was brighter, more uniform and more efficient. Since the cylindrical lens, focuses the light beam in one axis and converges the light bean the second axis, it added an angle to the light at the image plane, thus when this angled light strikes the scan target, it will reach areas that the collimated light would not contact and thus will scatter in more directions. This results in an increase in the range of angles that can be seen in BF and DF for different topographies. A richer image is thus presentable to the line sensors.

Explained differently, as compared to conventional BF DF systems where the light after the modulator is fully columnated, here the light is not columnated in the focused axis and the light in that axis has an angular component. If the axis it is focused in (with the angled light) is the same axis as the scanning is taking place in, the light is comes onto the target with a range of angles that are able to illuminate the defect on the surface of the target in more areas so there is a slight increase in the areas of the defect that are illuminated by the structured light and which can scatter the light. This additional amount of scattering allows for higher discrimination of surface defects at the line sensor.

The modulator wheel 70 provides structured light. It receives the elliptical beam from the cylindrical lens 68 and projects a known pattern (often grids or horizontal bars) that deform when striking the target so the line scan sensors (BF-DF cameras) can calculate defect depth, shape and size as well as other surface information.

Behind the modulator is a 1× relay/imaging lens 72 which images the now structured light with its encoding (modulator lines) from the modulator 70 and images and focuses it on the target (work surface) for examination. This lens focuses a sharp image of the structured light that comes from the modulator 70 onto the Si wafer target 2. This elliptical light illuminates only the shaped area of what the sensors can see.

The structured, encoded white light that strikes the Si wafer target 2 in the desired area is either reflected (spectral) light 102 or refracted light 104 depending on whether the photons strike a surface irregularity (defect) or just strike a planar face of the Si wafer 2. The refracted light 104 (still in an elliptical shape) is passed through a DF converging magnifying lens 106 placed at a distance from the DF line sensor camera 82 with a 3× magnification such that the sensor sees one-third less light but spaced across a three times greater area than what the light was at the front of the lens 106. This gives the line sensor camera 82 greater sensitivity so it can see more detail. The electric signal each pixel sends now represents a smaller area on the target.

There is more spectral light 102 than refracted light 104 coming off the target 2. This spectral light 102 (still in an elliptical shape) is passed through a BF converging magnifying image lens 108 placed at a distance from the BF line sensor camera 80 with a 5× magnification such that the sensor sees one-fifth less light but spaced across a five times greater area than what the light was at the front of the BF lens 108. This gives the line sensor camera 80 greater sensitivity so it can see more detail in the same fashion as described above with the DF sensor 82 and its DF converging magnifying lens 106.

The amount of light available to the BF sensor camera 80 is always much greater than that available to the DF sensor camera 82. With more photons reaching the BF image sensor, they can be spread out further and still retain the same resolution or detail as the DF sensor although there is a 5×:3× discrepancy in their respective magnifications. These magnification ratios of spectral light to refracted light are operationally set and do not reflect the discrepancy in their ratios of light (which varies but generally exceeds the 5:3 ratio). For this reason, there are a pair of polarizers 110 and 112 that serve to choke off the light going to the BF sensor 62. In cases where the sensors are running at their full speed (commonly 300 kHz) they don't have a lot of dynamic range to change their exposure time so whatever light the sensor sees is what it sees. Since the targets vary, there is no way to know what the ratio of spectral light to refracted light will be and there must be a mechanism to set the amount of light that gets to one sensor relative to the other sensor to get quality data in both channels at the same time. So, using the polarizers 110 and 112, the signal is lowered on the BF to match the fastest frame rate that the DF sensor can operate at with the illumination level of the provided light.

As illustrated, this improved bright field dark field metrology system can run its sensors at a faster frame rate while obtaining better data because the light reaching its line sensors (reflected or refracted) is brighter and has a more uniform photon density. Additionally, because of the angular component introduced into the light before it becomes structured, allows an enhanced examination area of the surface defects. The overall result is an improved surface examination having more precise results and which can be performed at a higher speed. The next improvement adds the effect of coordination motion to the metrology system thus introducing a common frame of reference that is linked to every single scan point of the point data cloud.

Looking at FIG. 12 the coordinated motion BF-DF metrology module can best be explained. Here, BF-DF metrology employs simultaneous, coordinated motion of the modulator wheel 70 about its A axis, the BF-DF camera shuttering, the metrology stage movement in the X or Y axis and/or the metrology chuck rotational (theta) motion about the C axis. This coordinated motion allows for a common frame of reference for the point cloud data to be established, wherein each individual data point is assigned a positional coordinate within a positional reference system (X, Y, C). This system allows for repeated scans with the same results, minimalized stitching, higher scanning speed, better resolution and faster back-end data processing, as the precise location of each data point or pixel in the point cloud of pixelated data generated by the BF-DF cameras, is known and can be dimensionally linked to every other data point.

Looking at FIG. 12, the Si wafer 2 resides on top of the chuck 30 that is connected to C axis motor assembly. (The motor assembly includes the motor 126, the mechanical linkage 128 that enables it to move the chuck 4, and the position/speed sensor 130.) The vertical distance or gap between the chuck 30 and the BF camera 80, DF camera 82, and the two area scan alignment cameras (macro camera 132 with a large field of view used for navigation, and micro camera 134 with higher magnification used for wafer alignment) is adjusted to focus the various cameras. The BF and DF cameras 80 and 82 and the two alignment cameras 132 and 134 on the metrology stage 140, are selected to have similar focal lengths allowing each pair to be focused in unison. The C axis motor assembly (similarly comprising motor 126, mechanical linkage 128 and position/speed sensor 130) enables the rotational movement of the chuck 30, around the C axis. the Z axis motor assembly 142, 144, 146 is connected to the metrology stage 140 and moves the stage 140 in the Z axis to focus the cameras.

The BF and DF cameras 80 and 82 are line scan cameras that capture linear pixelated scan strips of the structured light as it is reflected and refracted off the Si wafer's surface. Preferably, the camera's pixel array is greater than 9000 pixels in length and less than 10 pixels in height, and in the preferred embodiment is approximately 16,000 pixels long and 1 pixel high. These BF-DF cameras are electronically connected to a main computer for the transfer of point cloud data (pixelated image data). The BF-DF cameras are also connected to the motion controller 34, which triggers their shuttering in coordination with the movement of the metrology stage 140 and the passage of structured light 42 through the slits 150 in the modulator wheel 70. In the preferred embodiment, the BF camera collects images reflected at approximately 45 degrees from face of the wafer and the DF camera collects images refracted at approximately 90 degrees from the face of the wafer.

The macro camera 132, and micro camera 134 are used for the location and positioning of the Si wafer 2 on the chuck 30. Their purpose is to provide images of the locating indicia on the Si wafer 2 to the main computer 22.

The metrology stage 140 is suspended above the chuck 30 and has an X axis motor assembly 152, 154, 156 that moves the stage 140, and the devices mounted thereon in the X axis direction, and a Y drive motor assembly 158, 160, 162 that moves the stage 140 in the Y axis direction. The Z axis motor assembly that adjusts the gap between the metrology chuck and metrology stage to focus the four cameras is connected to the metrology stage, however in other embodiments it may be connected to the metrology chuck.

The light source 48 is mounted on the metrology stage 140 that projects a structured light 42 through the slits 150 of a modulator wheel 70. In the preferred embodiment this structured light 42 has an elliptical configuration 164 and is collimated in one axis (preferably the X axis) and angled in the other axis (preferably the Y axis). (See FIGS. 7-10) The modulator wheel 70 has a planar configuration with radial slits 150 spaced about its perimeter. The modulator wheel 70 is rotatable about the A axis by the modulator motor assembly 170, 172, 174 which is connected to the modulator wheel 70. This elliptical light 42 is projected through the slits 150 on the modulator wheel 70 to provide the elliptical, structured scan light 42 onto the surface of the Si wafer 2 at a scan angle (in the preferred embodiment this is an acute angle).

As noted above, each X, Y, Z, A and C axis motor assembly has an associated motor, a mechanical linkage and a position sensor. All position sensors are in communication with and reporting position data in real time to the main computer 22, that can be used to algorithmically determine the position and speed of the associated devices in real time. Knowing these positions, the main computer 22 can algorithmically manage the coordinated motion (synchronization) of the metrology stage 140 in the X and Y axes as well as the pulsing of the light 42 through the rotation of the modulator wheel by sending X, Y, and A motor drive signals, and a camera shuttering command to the motion controller 60.

The main computer 22 is in communication with the four cameras and the five position sensors. It has an image processing module 180 that receives pixelated data points of the scanned Si wafer which together form the data point cloud from the BF-DF camera. It receives, algorithmically processes and stores this pixelated data. When processed, this data provides a three-dimensional representation of the wafer and all its semiconductor and transistor components that can be used to verify the integrity of the devices on the wafer.

The main computer 22 also has a coordinated motion module 182 that processes positional and speed data from the positional sensors to use generating signals it sends to the coordinated motion controller 34.

The coordinated motion controller 34 is connected to the main computer 22, the X, Y, Z, C and A motors assemblies, the BF-DF cameras 80 and 82 and the light source 48. Upon the receipt of a signal from the main computer's alignment module 180 or coordinated motion module 182, it provides extremely precise coordinated drive signals to the various components to accomplish the following tasks: focus the cameras in the Z axis, align the wafer to its theta reference coordinate position in C axis, drive the metrology stage 140 in the X or Y axes, rotate the modulator wheel 70 in the A axis, turn on/off the light source 48 and operate the shuttering of the BF and DF cameras. During wafer scanning, the coordinated motion controller 34 keeps the motion of the various devices coordinated for the collection of pixelated images that are each related through a common frame of reference and coordinated in their motions.

The main computer 22 is connected to the motion controller 34 and provides logic instructions to the motion controller 34 for the operation of the five motor assemblies and the BF-DF cameras 80 and 82, to focus the four cameras in the Z axis, drive the metrology stage 140 in the X and Y axes, rotate the modulator wheel 70 in the A axis, rotate the metrology chuck 30 in the C axis, and operate the BF-DF camera's shuttering in coordinated motion and time to allow the acquired image to be tagged with a positional coordinate from a common frame of reference.

The main computer 22 has an alignment module 180 that has the customer's wafer map stored therein its memory. This wafer map is provided by the client (the entity having the semiconductors/transistors fabricated on that Si wafer 2) and provides the layout of the wafer showing everything on the wafer and its location. This includes the semiconductors/transistors as well as the positional indicia. These positional indicia may include edge notches 184, fiducial crosses 186 and center markings. The alignment module 180, using the images showing the positional indicia of the Si wafer 2 provided by the area scan alignment cameras 132 and 134, in conjunction with the wafer map, accurately determines the Si wafer's position on the metrology chuck 30. The wafer 2 will not have been placed in its perfect alignment position by the end effectors of the robotic arm that placed the wafer on the metrology chuck 30, although it will be close. Generally, the wafer will be placed in an offset position with respect to the alignment of the center of the Si wafer to the center of the metrology chuck 30 with respect to the X-Y axes or in an angular rotation in theta (Z axis) from its predetermined precise alignment position (the reference position).

For coordinated motion metrology to work, the wafer scan must begin in a common frame of reference with the wafer in its X Y C (0,0,0) reference coordinate reference position where C is the theta rotation in the Z axis. The pattern on the wafer must be aligned to the axis of the scanning system. The main computer's alignment module 180 uses the alignment camera's images, to algorithmically generate and provide a drive signal to the motion controller 34 to operate the C axis motor assembly to precisely rotate the metrology chuck 30 to the alignment position, as well as to determine an X-Y offset for the Z axis in the computer software. This offset eliminates the offset of the wafer placement from the center of the chuck and thus can determine the necessary metrology stage's X and Y axis movement instructions sent to the motion controller to compensate for this initial misalignment. This level of positional precision is needed to align the wafer's grid to that of the wafer map. The alignment module 180 is responsible for aligning the wafer 2 to the reference coordinate system.

Once the Si wafer 2 has been precisely placed, adjusted and dimensionally located on the chuck 30, a XYC positional coordinate starting reference position 0, 0, 0 is assigned in the main computer 22. From this point on, with the main computer's coordinated motion of the metrology stage in the X and Y axis, in conjunction with the shuttering of the BF-DF line scan cameras, coincident with the passage of the structured light through the modulator wheel slits 150 onto the scan surface of the Si wafer, each of the data points in the point cloud that is provided to the main computer, is linked to a positional coordinate system based on a known reference position (0, 0, 0).

With the wafer 2 linked to the known positional (coordinate) reference frame, scanning the wafer while dynamically coordinating the scan elements of the X or Y axis metrology stage linear movement, (and optionally, the metrology chuck's theta rotation), the A axis rotational speed of the modulator wheel 70, and the shuttering of the BF-DF line scan cameras 80 and 82, allows a precise three-dimensional imaging of the Si wafer's surface to be processed that requires a minimal, if any, photo data stitching. This coordinated motion and data acquisition provides a much more precise imaging, allows scanning to proceed at a faster rate, allows the image date to be parsed out in smaller bundles for simultaneous processing, and allows for a narrower field of view from the BF-DF cameras. All which add up to a much faster, more precise data processing to generate the Si wafer's surface mapping.

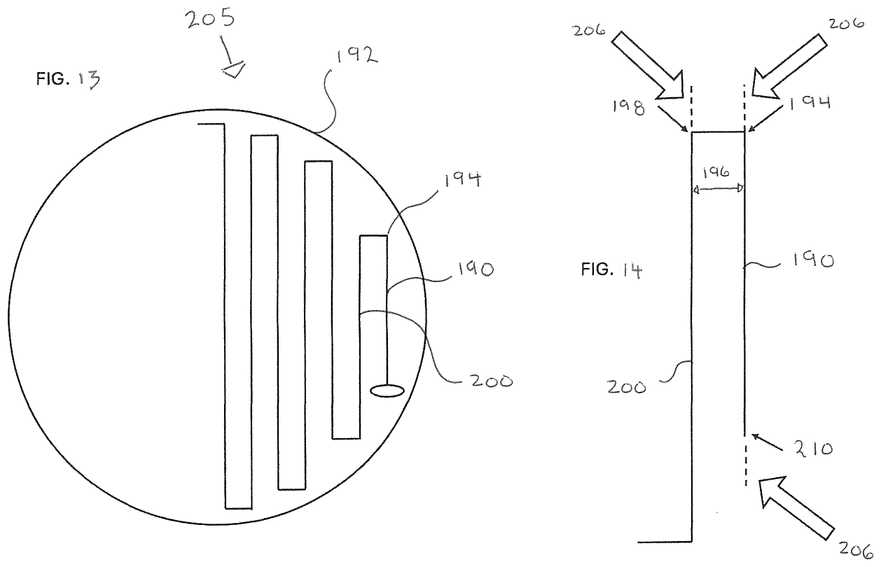

In general terms of operation, after the wafer is precisely rotationally located in theta on the chuck 30, and the dimensional offset has been determined with the compensating positional coordinates input to the computer's software, the scanning can begin. Generally, the scanning will proceed with a back and forth offset pattern accomplished by the metrology stage's movement in the X axis. (See FIGS. 13 and 14) The X axis motor assembly 152, 154 and 156 traverses the metrology stage linearly in the X axis above the wafer on the metrology platter 30, such that the elliptical light 42 traces a first X axis linear path 190 within the edges 192 of the wafer. Upon reaching the end of the first X axis linear path 194 the Y axis motor assembly 158, 160 and 162 will move and offset the metrology stage 30 in the Y axis direction an offset amount 196 to the beginning of the next X axis path 198 to offset the X axis location in the Y axis slightly less than the width of the light's ellipse 42 on the wafer. The X axis motor assembly 152, 154, 156 will traverse the metrology stage 300 in the second X axis linear path 200 (which runs parallel to the first X axis linear path 190) again within the edges 192 of the wafer. At this point, another Y axis offset will be performed and this X axis and Y axis stage movement pattern 205 repeated with varying X axis linear paths until the entire wafer has been scanned.

To ensure precise, repeatable scans within a few pixels, there must be no mechanical variation in the speed of the linear movement of the metrology stage 30 (and optionally, if used for circular scanning, the rotational motion in the theta axis of the metrology chuck) and the rotational speed of the modulator wheel 70. Since the BF-DF camera shuttering is purely electronic, the shuttering has immediate precision timing control by the computer/motion controller. It is imperative that all the coordinated motion does not slip out of synchronization as to do so would lose the ability for the scan image pixels to be precisely located with respect to the positional frame of reference. However, the motor assemblies cannot instantaneously bring their driven devices to their desired operating speeds and must go through an acceleration phase before being stabilized at this desired operating speed. This acceleration phase of the metrology would take the movement of the metrology stage, the modulator wheel and the BF-DF shuttering out of coordinated motion. To avoid this, there is an X axis pre-scan runup position 206 for any X axis path of the scan, is backed up behind the X axis scan start position 210 for that path (indicated by the dashed lines and hollow arrow in FIG. 14). The modulator wheel 70 is similarly placed in its pre scan runup position a short rotational distance in the A axis in front of its scan start position. The motion controller 34 initiates the X axis motor and the A axis motor and by the time the metrology stage and the modulator wheel reach their scan start positions, they are up to program speed. As they reach their scan start positions, stabilized at their full operating (program) speeds the light source 48 is switched on to provide elliptical light through the slits 150 in the modulator wheel 70 to provide the elliptical structured light 48 at the reference position of the wafer, and simultaneously the shuttering of the BF-DF cameras begins to collect the reflected and refracted images.

When the metrology stage reaches the end of any X axis linear path 190, the light source 48, the A axis motor assembly, the X axis motor assembly and the camera shuttering are each powered off by the motion controller 34. The metrology stage 30 is then moved in the Y axis the offset amount 196 and the metrology stage 30 is positioned to its X axis pre scan runup position 206 before its next X axis scan start position. The modulator wheel 70 undergoes a similar pre scan runup rotational positioning.

In conventional BF-DF metrology systems the X axis metrology stage would trigger the camera shuttering, but the positions were not coordinated, thus if the wafer was scanned multiple times, the same scanned feature part of the wafer would appear in different images each time because there was no positional reference point linked to an established positional frame of reference. The measurements were thus impossible to repeat because in each scan the position of the feature in the pixelated image frame would shift because of the different, non-coordinated positions of the X axis and the modulator wheel's angle as the image was acquired. This type of scanning would then require excessive oversampling, excessive algorithmic processing and image stitching to create a crude representational image of the Si wafer's surface.

In Summary, the process flow for semiconductor fabrication takes too much time to measure wafers in a separate metrology module. This Smart EFEM has increased robotic wafer handling capacity that allows for idle wafers to be undergo metrology scanning utilizing the coordinated motion BF-DF metrology device 28 in conjunction with the elliptical source light. The standard pre-aligner chuck will be replaced with a special larger, dual purpose wafer alignment/metrology chuck 30 and will have the metrology module positioned above the pre-alignment module. This will enable high resolution metrology data to be collected at every process step with no impact to processing cycle time inside the EFEMs. This Smart EFEM will allow full wafer tracking throughout the entire fabrication process for every wafer. This data will be AI pattern analysis to diagnose issues in the process stream.

Embodiments are described herein, and illustrated in the drawings, in terms of functional blocks, units and/or modules. Those skilled in the art will appreciate that these blocks, units and/or modules can be physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

Having described and illustrated the principles of the inventive concept with reference to illustrated embodiments, it will be recognized that the illustrated embodiments can be modified in arrangement and detail without departing from such principles and can be combined in any desired manner. And although the foregoing discussion has focused on a particular embodiment, other configurations are contemplated. Consequently, in view of the wide variety of permutations to the embodiments described herein, this detailed description and accompanying material is intended to be illustrative only and should not be taken as limiting the scope of the inventive concept.

Having thus described the invention, what is claimed as new and desired to be secured by Letters Patent is as follows:

1. A smart equipment front end module (EFEM) connectable to a semiconductor wafer process module that integrates a pre-alignment module with a metrology module to achieve greater Si wafer throughput, comprising:
an EFEM walled enclosure having a wall penetration;
a wafer loading port located in said wall penetration, said wafer loading port adapted to accept a wafer carrier;
a pre-alignment module within said EFEM walled enclosure;
a metrology module within said EFEM walled enclosure,
a pre-alignment/metrology chuck within said EFEM walled enclosure, said chuck positioned between said pre-alignment unit and said metrology unit;
a robotic wafer handler inside said EFEM walled enclosure, having at least one robotic arm extendable between said wafer carrier, said chuck and said semiconductor wafer process module;
a main computer connected to said pre-alignment module, said robotic wafer handler and said metrology module to affect a movement of Si wafers between said pre-alignment module, said metrology module and said wafer processing module, a coordinated motion of a metrology scan, and an alignment of the Si wafers on the chuck; and
wherein said metrology module is a bright field-dark field metrology module that uses light scan beam projected onto a Si wafer to provide reflected and refracted images that are acquired as scan images for processing into a dimensional image map of said Si wafer.

2. The smart equipment front end module (EFEM) of claim 1, wherein said light scan beam is an elliptical light scan beam to reflect and refract off a Si wafer surface to allow an acquisition of scan images.

3. The smart equipment front end module (EFEM) of claim 1, wherein said light scan beam has a first axis with collimated light rays and a second axis with angled light rays.

4. The smart equipment front end module (EFEM) of claim 2, wherein said elliptical light scan beam has a first axis with collimated light rays and a second axis with angled light rays.

5. The smart equipment front end module (EFEM) of claim 1 wherein said metrology module is a coordinated motion metrology module with a common frame of reference providing a positional coordinate for each acquired scan image.

6. The smart equipment front end module (EFEM) of claim 2 wherein said metrology module is a coordinated motion metrology module with a common frame of reference providing a positional coordinate for each acquired scan image.

7. The smart equipment front end module (EFEM) of claim 6 wherein said metrology module is a coordinated motion metrology module with a common frame of reference providing a positional coordinate for each acquired scan image.

8. The smart equipment front end module (EFEM) of claim 1 wherein said coordinated motion metrology module has a metrology stage that moves in a scan axis, a modulator wheel that rotates, and a bright field camera and dark field camera that shutter, all in coordinated synchronization.

9. The smart equipment front end module (EFEM) of claim 2 wherein said coordinated motion metrology module has a metrology stage that moves in a scan axis, a modulator wheel that rotates, and a bright field camera and dark field camera that shutter, all in coordinated synchronization.

10. The smart equipment front end module (EFEM) of claim 1 further comprising: a common frame of reference with positional coordinates for each scan image acquired.
